(19) United States
(12) Patent Application Publication
(10) Pub. No.: US 2011/0001199 A1
(43) Pub. Date: Jan. 6, 2011

(54) PRESSURE SENSOR AND PRESSURE SENSOR MANUFACTURING METHOD

(75) Inventors: Hirofumi Tojo, Tokyo (JP); Masayuki Yoneda, Tokyo (JP)

Correspondence Address: MCDERMOTT WILL & EMERY LLP, 600 13TH STREET, N.W., WASHINGTON, DC, 20005-3096, US

(73) Assignee: YAMATAKE CORPORATION, Tokyo (JP)

(21) Appl. No.: 12/830,787

(22) Filed: Jul. 6, 2010

(30) Foreign Application Priority Data
Jul. 6, 2009 (JP) 2009-159762

(51) Int. Cl. H01L 29/84; H01L 21/28

(52) U.S. Cl. 257/415; 438/50; 257/E29.324; 257/E21.158

(57) ABSTRACT

A pressure sensor having a second semiconductor layer wherein is formed diffused resistance interconnections, an insulating layer that is formed on top of the second semiconductor layer, and external conducting portions that are formed on top of the insulating layer, wherein contacts for connecting electrically between the external conducting portions and the diffused resistance interconnections are formed in the insulating layer, and wherein the external conducting portions are formed in ranges corresponding to the ranges wherein the diffused resistance interconnections are formed in the second semiconductor layer.

### CROSS REFERENCE TO RELATED APPLICATIONS

The present application claims priority under 35 U.S.C. §119 to Japanese Patent Application No. 2009-159762, filed Jul. 6, 2009, which is incorporated herein by reference.

### FIELD OF TECHNOLOGY

The present invention relates to a pressure sensor and to a pressure sensor manufacturing method, and, in particular, relates to a pressure sensor having a diaphragm, and to a method for manufacturing that pressure sensor.

### BACKGROUND OF THE INVENTION

Pressure sensors that use a semiconductor piezoresistance effect are small and light, and have high sensitivity, and thus are used broadly in fields such as industrial instrumentation and medicine. In a pressure sensor is set forth in Unexamined Japanese Patent Application Publication H06-102119 (“JP '119”), deformation gauges having a piezo effect and resistance portions are formed on a diaphragm of a semiconductor substrate. Additionally, an insulating layer having a contact holes is formed on the semiconductor substrate. Furthermore, connections are made, through the contact holes, between the resistance portions and electrode pads that are formed on top of the insulating layer.

However, in the pressure sensor as set forth in JP '119, it is not possible to prevent leakage current cause but insulating defects. FIG. 14 illustrates schematically a pressure sensor according to JP '119. As illustrated in FIG. 14, there are cases, for example, wherein flaw 206 in the insulating layer 204 under the electrode pad 205 may cause an insulating defect. In such cases, there will be leakage current from the electrode pad 205 to the semiconductor substrate 201 at the part 206 wherein there is the insulating defect. As a result, there will be error in the measurement for the current that flows in the strain gauge 202, and thus there is a problem in that this produces characteristic defects, such as detection errors, and the like. Furthermore, this also produces extraneous consumption of current.

The present invention is to correct problem areas such as this, and the object thereof is to provide a pressure sensor, and a pressure sensor manufacturing method, able to prevent the characteristic defects caused by leakage current.

### SUMMARY OF THE INVENTION

A pressure sensor as set forth in a first aspect according to the present invention is provided with a semiconductor substrate, an insulating layer, and an external conducting portion. An internal resistance portion is formed within the semiconductor substrate. Additionally, the insulating layer is formed on top of the semiconductor substrate. Additionally, the external conducting portion is formed on top of the insulating layer. Furthermore, a contact for connecting electrically between the external conducting portion and the internal resistance portion is formed in the insulating layer. Furthermore, the external conducting portion is formed in a range corresponding to the range wherein is formed the internal resistance portion on the semiconductor substrate.

In the first aspect according to the present invention, the external conducting portion is formed in a range corresponding to the range wherein is formed the internal resistance portion on the semiconductor substrate. In other words, the external conducting portion is formed on top of a range wherein the internal resistance portion is formed. Doing so means that the internal resistance portion is formed under the insulating defect when there is an insulating defect, such as a flaw in the insulating layer, that is positioned under the external conducting portion. Furthermore, because, ideally, the external conducting portion and the internal resistance portion are at the same electropotential, even if there is this insulating defect portion in the insulating layer, still there will be essentially no leakage current produced through the insulating defect portion. Additionally, even if a leakage current were produced through the insulating defect portion, it would only be an electric current from the external conducting portion to the internal resistance portion that are already connected electrically through the contact. Because of this, there would be no impact on the characteristics of the pressure sensor. Consequently, this is able to prevent characteristic defects caused by the leakage current.

A pressure sensor as set forth in a second aspect according to the present invention is provided with a semiconductor substrate, an insulating layer, and an external conducting portion. A plurality of internal resistance portions is formed within the semiconductor substrate. Additionally, the insulating layer is formed on top of the semiconductor substrate. Additionally, a plurality of external conducting portions is formed on top of the insulating layer. Furthermore, a plurality of contacts for connecting electrically between the external conducting portion and the internal resistance portion is formed in the insulating layer. Furthermore, the external conducting portion is formed in a range corresponding to the range wherein is formed the internal resistance portion on the semiconductor substrate.

The second aspect according to the present invention produces the same effect as the first aspect.

Additionally, preferably the semiconductor substrate is an n-type semiconductor substrate, where the internal resistance portions are made from p-type semiconductors, where a voltage is applied so that those parts of the semiconductor substrate that are not formed into the internal resistance portions will be at the same electropotential or higher than that of the external conducting portions, and so that the potential difference formed between the internal resistance portions of the semiconductor substrate and those parts of the semiconductor substrate that are not formed into the internal resistance portions will be less than the breakdown voltage.

Additionally, preferably the semiconductor substrate is a p-type semiconductor substrate, where the internal resistance portions are made from n-type semiconductors, where a voltage is applied so that those parts of the semiconductor substrate that are not formed into the internal resistance portions will be at the same electropotential or lower than that of the external conducting portions, and so that the potential difference formed between the internal resistance portions of the semiconductor substrate and those parts of the semiconductor substrate that are not formed into the internal resistance portions will be less than the breakdown voltage.

Doing so makes it possible to suppress to a trivial amount the current from the external conducting portions to the portions of the semiconductor substrate that are not formed into the internal resistance portions. Consequently, this is able to prevent more effectively the characteristic defects in the pressure sensor.

Furthermore, the number of contacts that are provided in the insulating layer is preferably equal to the number of external conducting portions or less than the number of external conducting portions.

If the number of contacts is high, then, structurally, there will be a greater likelihood to be affected by stresses other than pressure. The present invention suppresses the number of contacts to the minimum requirement, making it possible to reduce the effects of stresses other than pressure.

A pressure sensor manufacturing method as set forth in a third aspect according to the present invention is provided with an internal resistance portion forming process, an insulating layer forming process, an external conducting portion forming process, and a contact forming process. In the internal resistance portion forming process, the internal resistance portions are formed in the semiconductor substrate. Additionally, in the insulating layer forming process, the insulating layer is formed on top of the semiconductor substrate. In the external conducting portion forming process, the external conducting portions are formed on top of the insulating layer. Furthermore, in the contact forming process, the contacts for connecting electrically between the external conducting portion and the internal resistance portion are formed in the insulating layer. Furthermore, in the external conducting portion forming process, the external conducting portions are formed in ranges corresponding to the ranges wherein are formed the internal resistance portions on the semiconductor substrate.

In the third aspect according to the present invention, the external conducting portion is formed in a range corresponding to the range wherein is formed the internal resistance portion on the semiconductor substrate. In other words, the external conducting portion is formed on top of a range wherein the internal resistance portion is formed. Doing so means that the internal resistance portion is formed under the insulating defect when there is an insulating defect, such as a flaw in the insulating layer, that is positioned under the external conducting portion. Furthermore, because, ideally, the external conducting portion and the internal resistance portion are at the same electropotential, even if there is this insulating defect portion in the insulating layer, still there will be essentially no leakage current produced through the insulating defect portion. Additionally, even if a leakage current were produced through the insulating defect portion, it would only be an electric current from the external conducting portion to the internal resistance portion that are already connected electrically through the contact. Because of this, there would be no impact on the characteristics of the pressure sensor. Consequently, this is able to prevent characteristic defects caused by the leakage current.

Furthermore, preferably in the contact forming process, the number of contacts that are formed in the insulating layer is preferably equal to the number of external conducting portions or less than the number of external conducting portions.

If the number of contacts is high, then, structurally, there will be a greater likelihood to be affected by stresses other than pressure. The present invention suppresses the number of contacts to the minimum requirement, making it possible to reduce the effects of stresses other than pressure.

The present invention is able to prevent characteristic defects caused by the leakage current.

### BRIEF DESCRIPTION OF THE DRAWINGS

FIG. 1 is a top view illustrating the structure of a pressure sensor according to a form of embodiment according to the present invention.

FIG. 2 is a cross-sectional diagram along the section II-II of the sensor chip illustrated in FIG. 1.

FIG. 3 is a cross-sectional diagram along the section of the sensor chip illustrated in FIG. 1.

FIG. 4 is a cross-sectional diagram along the section IV-IV of the pressure sensor illustrated in FIG. 1.

FIG. 5 is a diagram illustrating a manufacturing process for a sensor chip according to a form of embodiment.

FIG. 6 is a diagram illustrating a manufacturing process for a sensor chip according to a form of embodiment.

FIG. 7 is a process cross-sectional diagram illustrating a manufacturing process for a sensor chip according to a form of embodiment.

FIG. 8 is a process cross-sectional diagram illustrating a manufacturing process for a sensor chip according to a form of embodiment.

FIG. 9 is a process cross-sectional illustrating the fabrication process for a pressure sensor according to a form of embodiment.

FIG. 10 is a process cross-sectional illustrating the fabrication process for a pressure sensor according to a form of embodiment.

FIG. 11 is a process cross-sectional illustrating the fabrication process for a pressure sensor according to a form of embodiment.

FIG. 12 is a process cross-sectional illustrating the fabrication process for a pressure sensor according to a form of embodiment.

FIG. 13 is a cross-sectional diagram for explaining the effect on the characteristics of an insulating defect in the insulating layer in a pressure sensor according to a form of embodiment according to the present invention.

FIG. 14 is a cross-sectional diagram for explaining the effect on the characteristics of an insulating defect in the insulating layer in a conventional pressure sensor.

### DETAILED DESCRIPTION OF THE INVENTION

A form of embodiment according to the present invention will be explained below in reference to the drawings.

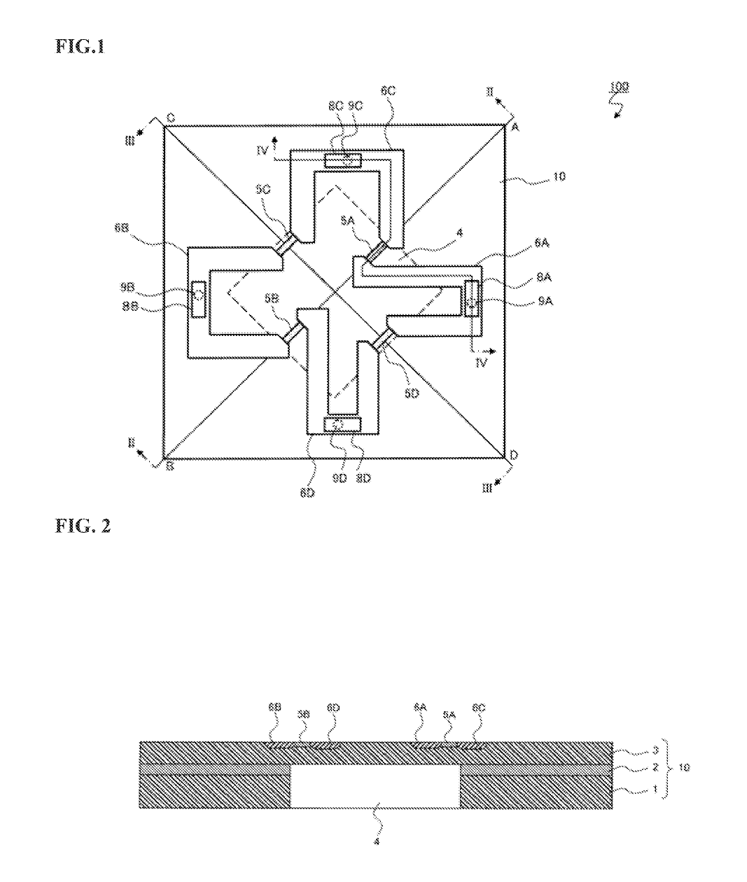

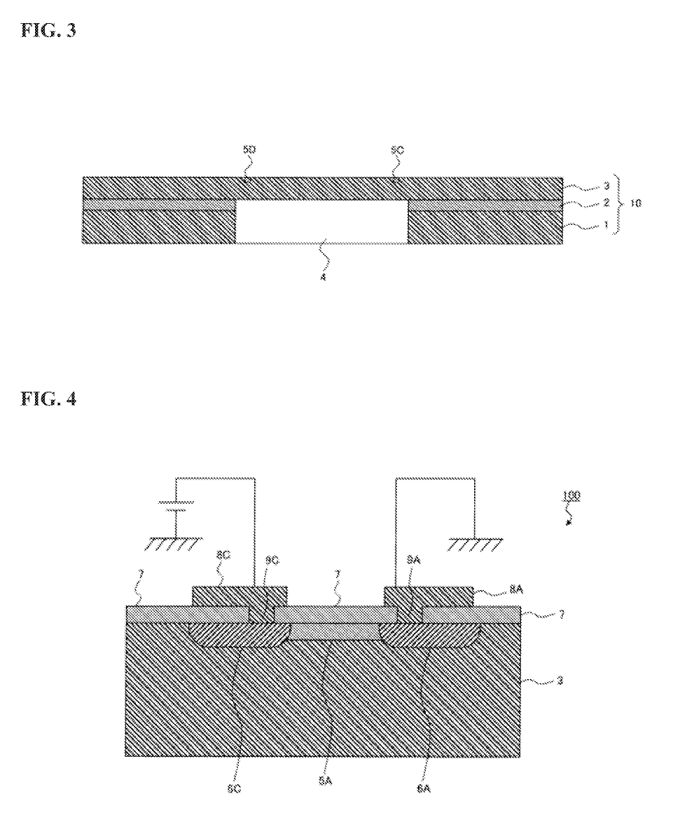

In the below, a specific form of embodiment wherein the present invention is applied will be explained in detail while referencing the drawings. FIG. 1 is a top view illustrating the structure of a pressure sensor 100 according to the present form of embodiment. FIG. 2 is a cross-sectional diagram along the section II-II of the sensor chip 10 illustrated in FIG. 1, and FIG. 3 is a cross-sectional diagram along the section of the sensor chip 10 illustrated in FIG. 1. The pressure sensor 100 according to the present form of embodiment is a semiconductor sensor that uses the piezoresistance effect of semiconductors.

The pressure sensor 100 has a sensor chip 10 that is made out of a semiconductor substrate. The sensor chip 10 is a square shape. As illustrated in FIG. 1, the corners of the square sensor chip 10 are defined as A, B, C, and D. As illustrated in FIG. 1, the upper-right corner is defined as corner A, the lower-left corner is defined as corner B, the upper-left corner is defined as corner C, and the lower-right corner is defined as corner D. The diagonal line connecting corner A and corner B is defined as the diagonal line AB. The diagonal line connecting the corner C and the corner D is defined as the diagonal line CD. The sensor chip 10 is a square, and thus the diagonal line AB and the diagonal line CD bisect each other at right angles.

As illustrated in FIG. 2, the sensor chip 10 has a three-layer structure with a first semiconductor layer 1, which is a base, an insulating layer 2, and a second semiconductor layer 3 (a semiconductor substrate). For example, an SOI (Silicon On Insulator) substrate, comprising a first semiconductor layer 1, an insulating layer 2 with a thickness of about 0.5 μm, and a second semiconductor layer 3, may be used as the sensor chip 10. In the present example of embodiment, the first semiconductor layer 1 and the second semiconductor layer 3 is structured from n-type single crystal silicon layers. The insulating layer 2 may be structured from, for example, an SiO₂ layer. The insulating layer 2 is formed on top of the first semiconductor layer 1. Additionally, the second semiconductor layer 3 is formed on top of the insulating layer 2. Consequently, the insulating layer 2 is disposed between the first semiconductor layer 1 and the second semiconductor layer 3. The insulating layer 2 functions as an etching stopper when etching the first semiconductor layer 1. The second semiconductor layer 3 structures a differential pressure diaphragm 4 (diaphragm portion). As illustrated in FIG. 2, the differential pressure diaphragm 4 is disposed in the center part of the chip.

The differential pressure diaphragm 4, for detecting a differential pressure, is disposed in the center part of the sensor chip 10. As illustrated in FIG. 2, the differential pressure diaphragm 4 is formed by removing the first semiconductor layer 1. That is, the sensor chip 10 is thinned at the differential pressure diaphragm 4. As illustrated in FIG. 1, here the differential pressure diaphragm 4 is formed in the shape of a square. Additionally, the center of the differential pressure diaphragm 4 is coincident with the center of the sensor chip 10. That is, the center point of the sensor chip 10 is on the point of intersection between the diagonal line AB and the diagonal line CD. Additionally, the differential pressure diaphragm 4 is disposed angled at 45° relative to the square sensor chip 10. Consequently, the diagonal line AB passes perpendicularly through the center of two opposing edges of the differential pressure diaphragm 4. Additionally, the diagonal line CD passes perpendicularly through the centers of the other two opposing edges of the differential pressure diaphragm 4.

Differential pressure gauges 5A through 5D are disposed on the surface of the p-type differential pressure diaphragm 4. These four differential pressure gauges 5A through 5D are referred to, in aggregate, as the differential pressure gauges 5. The differential pressure gauges 5 are disposed at the edge portions of the differential pressure diaphragm 4. Here a single differential pressure gauge 5 is disposed near the center of each edge of the square differential pressure diaphragm 4. A differential pressure gauge 5 is disposed in the center of each edge of the differential pressure diaphragm 4. Consequently, the differential pressure gauge 5A is disposed between the center of the differential pressure diaphragm 4 and the corner A. The differential pressure gauge 5B is disposed between the center of the differential pressure diaphragm 4 and the corner B, the differential pressure gauge 5 C is disposed between the center of the differential pressure diaphragm 4 and the corner C, and the differential pressure gauge 5D is disposed between the center of the differential pressure diaphragm 4 and the corner D. The differential pressure gauge 5A and the differential pressure gauge 5B face each other with the center of the sensor chip 10 therebetween. The differential pressure gauge 5C and the differential pressure gauge 5D facing each other with the center of the sensor chip 10 therebetween.

The differential pressure gauges 5 are strain gauges having the piezoresistance effect. Consequently, when the sensor chip 10 deforms, the resistances of each of the differential pressure gauges 5A through 5D will change. Note that, on the top surface of the sensor chip, p-type diffused resistance interconnections 6A through 6D are formed connecting the individual differential pressure gauges 5A through 5D. For example, as illustrated in FIG. 1, here the diffused resistance interconnections 6A through 6D are formed in essentially U-shapes in the plan view. The terminal portions of the diffused resistance interconnections 6A through 6D are connected to both ends of each of the differential pressure gauges 5A through 5D. The combinations of the differential pressure gauges 5A through 5D and the diffused resistance interconnections 6A through 6D form a bridge circuit. The differential pressure diaphragm 4 deforms due to a pressure differential between the spaces partitioned by the differential pressure diaphragm 4. In the differential pressure gauges 5, the resistances vary in accordance with the amount of deformation of the differential pressure diaphragm 4. The pressure can be measured by detecting these variations in the resistances. The differential pressure gauges 5 are formed on the surface of the sensor chip 10 as illustrated in FIG. 2 and FIG. 3.

The four differential pressure gauges 5A through 5D are disposed in parallel with each other. That is, the lengthwise directions of the four differential pressure gauges 5A through 5D are disposed along the diagonal line AB. Additionally, diffused resistance interconnections 6A through 6D are connected to both ends of the differential pressure gauges 5A through 5D in the lengthwise direction. The differential pressure gauges 5 are formed in the parallel to the <110> crystal axial direction wherein the piezoresistance factor is maximized in the (100) crystal face orientation of the sensor chip 10. Note that the pressure sensor 100 bridge circuit pattern in the present invention is not limited to that which is illustrated in FIG. 1.

Additionally, as illustrated in FIG. 1, the width of the diffused resistance interconnection 6 is relatively wide. Doing so causes the resistance value of the diffused resistance interconnection 6 to be relatively low. On the other hand, as illustrated in FIG. 1, the width of the differential pressure gauge 5 is relatively narrow. Doing so causes the resistance value of the differential pressure gauge 5 to be relatively high. This causes the diffused resistance interconnection 6 and the differential pressure gauge 5 to work cooperatively to form a bridge circuit.

Additionally, the differential pressure gauges 5A through 5D and the diffused resistance interconnections 6A through 6D that form the bridge circuit are covered by the insulating layer (the oxide layer) 7, as illustrated in FIG. 4, except for the contacts 9 A through 9D, as described below.

Additionally, in the specific position of each individual diffused resistance interconnection 6A through 6D of the bridge circuit that is formed through the combination of the differential pressure gauges 5 and the diffused resistance interconnections 6, the contact 9 A through 9D that is formed is formed passing through a portion of the insulating layer 7. Note that in the case of the present form of embodiment, two contacts 9 are formed for applying electric power to the bridge circuit, and two contacts 9 are formed for extracting the outputs from the bridge circuit. Consequently, the number of contacts 9 is no more than the number of the differential pressure bridge gauges.

The structure of the pressure sensor 100 according to the present form of embodiment will be explained next in reference to FIG. 4. FIG. 4 is a partial cross-sectional diagram along the section IV-IV in FIG. 1, illustrating a part of the layers that are above the second semiconductor layer in the pressure sensor 100. The pressure sensor 100, as illustrated in FIG. 4, comprises a differential pressure gauge 5, a diffused resistance interconnection 6 (internal resistance portion), an insulating layer 7, an external conducting portion, and the like.

Here the external conducting portions 8 are electrode pads, metal interconnections, or the like.

As illustrated in FIG. 4, p-type differential pressure gauges 5 are formed on the upper surface portion of an n-type second semiconductor layer 3. P-type diffused resistance interconnections 6 are formed with p-type differential pressure gauges 5 therebetween on the upper surface portion of the n-type second semiconductor layer 3. The p-type diffused resistance interconnections 6 and the differential pressure gauges 5 are formed in a portion of the n-type second semiconductor layer 3 that corresponds to the differential pressure diaphragm 4.

Additionally, the insulating layer 7 is formed on top of the second semiconductor layer 3. Additionally, the external conducting portions 8 are formed on top the insulating layer 7. Furthermore, contacts 9 for connecting electrically between the external conducting portions 8 and the internal resistance portions 6 are formed in the insulating layer 7. Furthermore, the number of contacts 9 that are formed in the insulating layer 7 is equal to the number of external conducting portions 8 that are formed on top of the insulating layer 7. Note that, the number of contacts 9 that are formed in the insulating layer 7 may be less than the number of external conducting portions 8 that are formed on top of the insulating layer 7.

Additionally, the external conducting portions 8 are formed in ranges corresponding to the ranges wherein are formed the p-type diffused resistance interconnections 6 in the n-type second semiconductor layer 3. In other words, the external conducting portions 8 are formed on top of the ranges wherein the p-type internal resistance portions are formed.

Additionally, a voltage is applied to those parts of the second semiconductor layer 3 that are not formed into the p-type diffused resistance interconnections 6 or into the differential pressure gauges 5 so as to be at the same electropotential or higher than that of the external conducting portions 8, and so that the potential difference formed between the diffused resistance interconnections 6 and the differential pressure gauges 5 of the second semiconductor layer 3 and those parts of the second semiconductor layer 3 that are not formed into the diffused resistance interconnections 6 or the differential pressure gauges 5 will be less than the breakdown voltage.

Here having the potential difference between the diffused resistance interconnections 6 and the differential pressure gauges 5 of the second semiconductor layer 3 and those parts of the second semiconductor layer 3 that are not formed into the diffused resistance interconnections 6 or the differential pressure gauges 5 be less than the breakdown voltage is because if this potential difference were to exceed the breakdown voltage, the pressure sensor would cease to function, and there would be the danger of destroying the pressure sensor. Specifically, if there were a large backward voltage from the n-type second semiconductor layer 3 to the p-type diffused resistance interconnections 6 and the differential pressure gauges 5, a sudden reverse current would result. Additionally, if the backward voltage were to exceed the specific breakdown voltage, the reverse current would suddenly increase, causing the pressure sensor to cease to function, and risking the destruction of the pressure sensor.

Note that if second semiconductor layer 3 is a p-type semiconductor substrate and the diffused resistance interconnections 6 and differential pressure gauges 5 are made from n-type semiconductor, then a voltage may be applied to those parts of the second semiconductor layer 3 that are not formed into the n-type diffused resistance interconnections 6 or into the differential pressure gauges 5 so as to be at the same electropotential or lower than that of the external conducting portions 8, and so that the potential difference formed between the diffused resistance interconnections 6 and the differential pressure gauges 5 of the second semiconductor layer 3 and those parts of the second semiconductor layer 3 that are not formed into the diffused resistance interconnections 6 or the differential pressure gauges 5 will be less than the breakdown voltage.

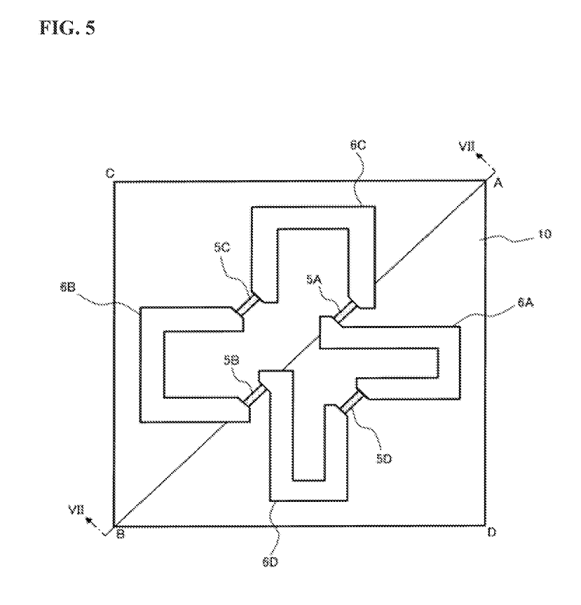

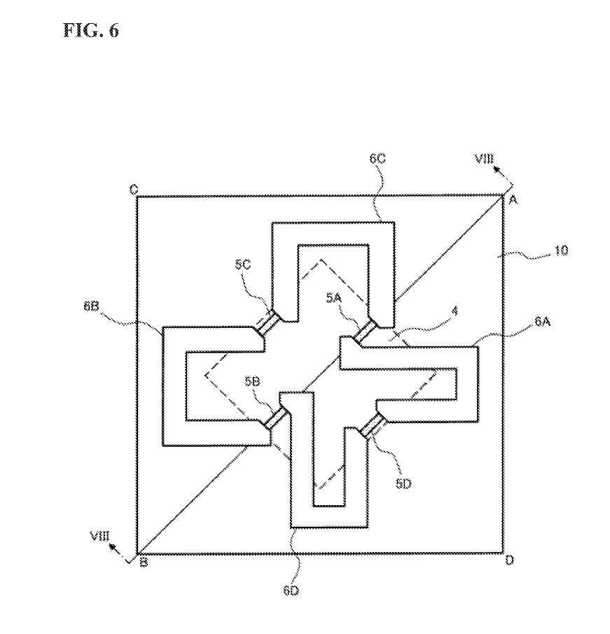

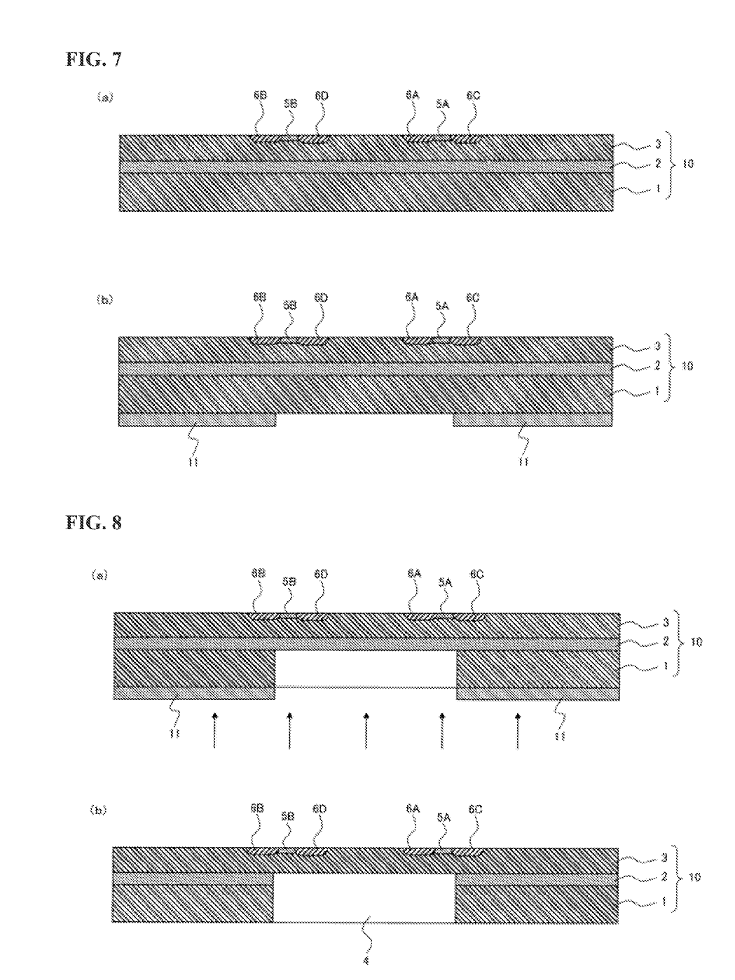

The method for manufacturing the sensor chip 10 will be explained next using FIG. 5 through FIG. 8. FIG. 5 and FIG. 6 are diagrams illustrating a method for manufacturing the sensor chip 10, and show the structure when the sensor chip 10 is viewed from above. FIG. 7 and FIG. 8 are diagrams illustrating a method for manufacturing the sensor chip 10, and, respectively show the structure along the cross-section VII-VII in FIG. 5 and the structure along the cross-section VIII-VIII in FIG. 6.

First an SOI (Silicon on Insulator) wafer is prepared having a first semiconductor layer 1, an insulating layer 2 with a thickness of about 0.5 μm, and a second semiconductor layer 3. In manufacturing this SOI wafer, the SIMOX (Separation by IMplanted OXygen) technology wherein an SiO₂ layer is formed through implanting oxygen into a silicon substrate, may be used, the SDB (Silicon Direct Bonding) technology wherein two selecting substrates are bonded together, may be used, or another method may be used. Note that the second semiconductor layer 3 may be planarized and thinned. For example, the second semiconductor layer 3 may be polished the to a specific thickness using a polishing method known as CCP (Computer-Controlled Polishing).

The differential pressure gauges 5A through 5D are formed from p-type silicon, through an impurity diffusing method or an ion implantation method, on the top surface of the second semiconductor layer 3. Specifically, the differential pressure gauge 5 is formed through diffusing an impurity (such as boron) into the top surface of the second semiconductor layer 3. Also, similarly, diffused resistance interconnections 6 are formed (internal resistance portion forming process) on either side of the differential pressure gauges 5 on the top surface of the second semiconductor layer 3. Doing so forms the structure illustrated in FIG. 5 and FIG. 7 (a). As illustrated in FIG. 1, and the like, each gauge is formed in a specific position of the location that will form each diaphragm. Note that the differential pressure gauges 5A through 5D and the diffused resistance interconnection 6 may instead be formed after the diaphragm forming process set forth below.

A resist 11 is formed on the bottom surface of the SOI wafer that is fabricated in this way. The pattern of the resist 11 is formed on the first semiconductor layer 1 through a well-known photolithography process. That is, a photosensitive resin layer is coated, exposed, and developed to form a pattern in the resist 11. The resist 11 has opening portions at parts that correspond to the pressure sensitive regions (the regions wherein the diaphragms will be formed). That is, the first semiconductor layer 1 is exposed in the parts wherein the diaphragms will be formed. Doing so forms the structure illustrated in FIG. 7 (b).

The first semiconductor layer 1 is etched using the resist 11 as a mask. Doing so forms the structure illustrated in FIG. 6 and FIG. 8 (a). Dry etching, for example, the well-known ICP etching, or the like, may be used to etch the first semiconductor layer 1. Of course, the first semiconductor layer 1 may instead be etched using a wet etching method that uses a solution such as KOH or TMAH. The differential pressure diaphragm 4 is formed when the first semiconductor layer is etched. Here the insulating layer 2 functions as an etching stopper. Consequently, the insulating layer 2 is exposed in the opening portions of the resist 11.

The structure illustrated in FIG. 8 (b) is formed when the resist 11 and the insulating layer 2 of the diaphragm portion 4 are removed. Doing so forms the sensor chip 10. Note that there is no particular limitation to the sequence of the process of forming the diffused resistance interconnection 6 and the strain gauge forming process.

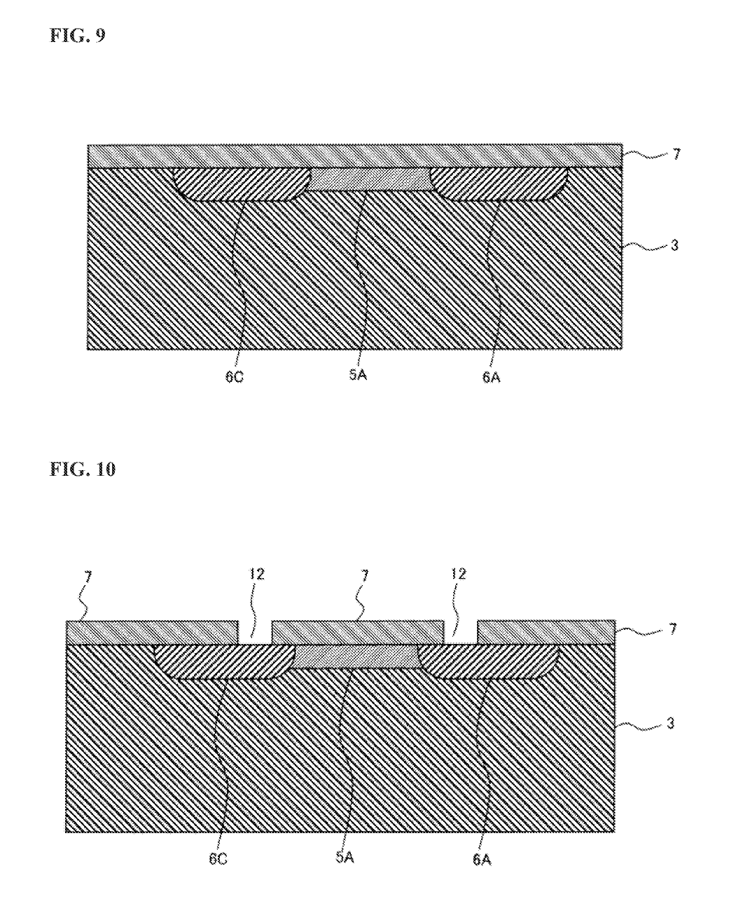

The method for forming the pressure sensor will be explained next using FIG. 9 through FIG. 12. FIG. 9 through FIG. 12 are process cross-sectional diagrams illustrating a method for forming the pressure sensor.

First, as illustrated in FIG. 9, the entire surface of the second semiconductor layer 3 is oxidized, to form the insulating layer 7 (the insulating layer forming process). Note that the insulating layer 7 may instead be formed through a CVD (Chemical Vapor Deposition) method or a sputtering method, or the like, on the top surface of the second semiconductor layer 3.

Contact holes 12 are formed next through performing etching, using a photolithography method, as illustrated in FIG. 10.

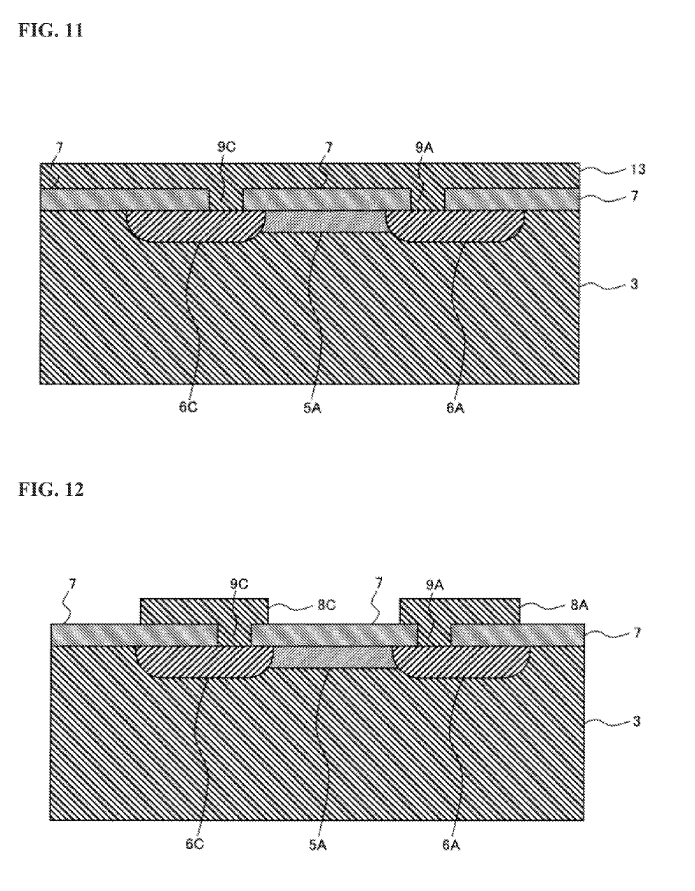

Following this, as illustrated in FIG. 11, a vapor deposition method or a sputtering method is used to deposit a metal layer 13 onto the top of the insulating layer 7 so as to fill the contact holes 12 (the contact forming process). The contact 9 are thereby formed in the contact hole 12 portions.

Following this, as illustrated in FIG. 12, etching is performed to form the external conducting portions 8 (the external conducting portion forming process). At this time, etching of the metal layer 13 is performed so that the ranges wherein the external conducting portions 8 are formed will be corresponding to the ranges wherein the diffused resistance interconnections 6 are formed. In other words, the etching of the metal layer 13 is performed so that the external conducting portions 8 will be formed over the ranges wherein the diffused resistance interconnections 6 are formed.

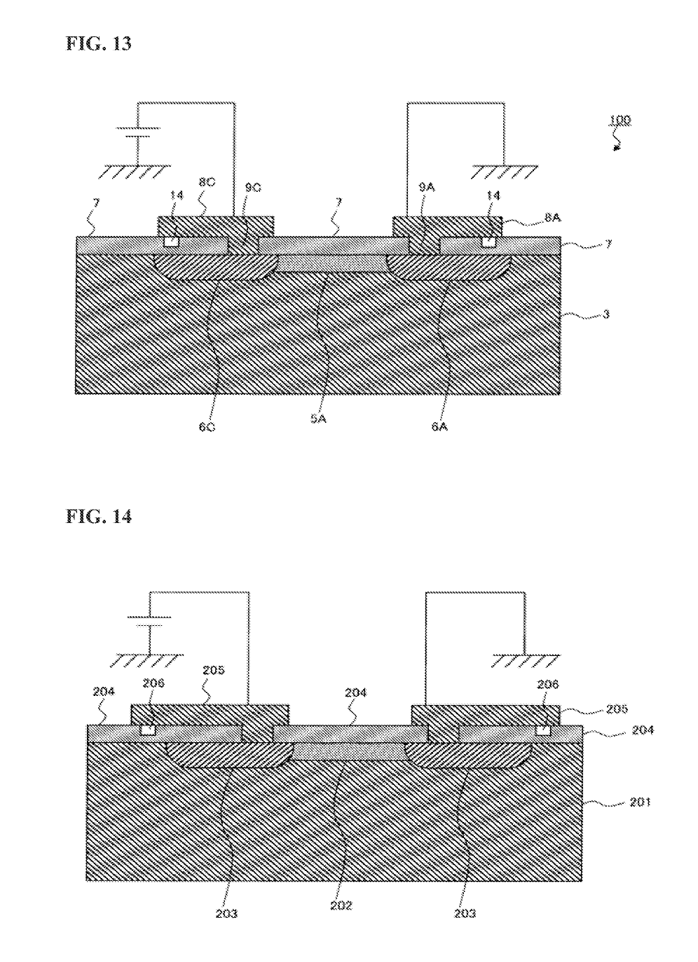

In the pressure sensor 100 according to an embodiment according to the present invention, the external conducting portions 8 are formed in ranges corresponding to the ranges wherein are formed the diffused resistance interconnections 6 in the second semiconductor layer 3. In other words, the external conducting portions 8 are formed on top of ranges wherein the diffused resistance interconnections 6 are formed. Doing so means that, as illustrated in FIG. 13, for example, a diffused resistance interconnection 6 is formed under the insulating defect portion 14 if there is an insulating defect portion 14, such as a flaw in the insulating layer 7, positioned under an external conducting portion 8. Furthermore, because, ideally, the external conducting portion 8 and the diffused resistance interconnection 6 are at the same electropotential, even if there is this insulating defect portion 14 in the insulating layer 7, still there will be essentially no leakage current produced through the insulating defect portion 14. Additionally, even if a leakage current were produced through the insulating defect portion 14, it would only be an electric current from the external conducting portion 8 to the diffused resistance interconnection 6 that are already connected electrically through the contact 9. Because of this, there would be no impact on the characteristics of the pressure sensor 100. Consequently, this is able to prevent characteristic defects caused by the leakage current.

Furthermore, if second semiconductor layer 3 is an n-type semiconductor substrate and the diffused resistance interconnections 6 and differential pressure gauges 5 are made from p-type semiconductor, then a voltage is applied to those parts of the second semiconductor layer 3 that are not formed into the p-type diffused resistance interconnections 6 or into the differential pressure gauges 5 so as to be at the same electropotential or higher than that of the external conducting portions 8, and so that the potential difference formed between the diffused resistance interconnections 6 and the differential pressure gauges 5 of the second semiconductor layer 3 and those parts of the second semiconductor layer 3 that are not formed into the diffused resistance interconnections 6 or the differential pressure gauges 5 will be less than the breakdown voltage.

Doing so makes it possible to suppress to a trivial amount the current from the diffused resistance interconnections 6 to the portions of the second semiconductor layer 3 that are not formed into the diffused resistance interconnections 6. Consequently, this is able to prevent more effectively the characteristic defects in the pressure sensor 100.

Note that if second semiconductor layer 3 is a p-type semiconductor substrate and the diffused resistance interconnections 6 and differential pressure gauges 5 are made from n-type semiconductor, then a voltage should be applied to those parts of the second semiconductor layer 3 that are not formed into the n-type diffused resistance interconnections 6 or into the differential pressure gauges 5 so as to be at the same electropotential or lower than that of the external conducting portions 8, and so that the potential difference formed between the diffused resistance interconnections 6 and the differential pressure gauges 5 of the second semiconductor layer 3 and those parts of the second semiconductor layer 3 that are not formed into the diffused resistance interconnections 6 or the differential pressure gauges 5 will be less than the breakdown voltage.

Furthermore, the number of contacts 9 that are provided in the insulating layer is equal to the number of external conducting portions 8 or less than the number of external conducting portions 8.

If the number of contacts 9 is high, then, structurally, there will be a greater likelihood to be affected by stresses other than pressure. The present invention suppresses the number of contacts 9 to the minimum requirement, making it possible to reduce the effects of stresses other than pressure.

Note that in the pressure sensor 100 as set forth in the present invention, there is no limitation to the layout pattern for the individual gauges, or the like, to that which is in the present form of embodiment.

Additionally, the ranges wherein the external conducting portions 8 are formed may be controlled so that the ranges wherein the external conducting portions 8 are formed will be within ranges that correspond to the ranges wherein the diffused resistance interconnections 6 are formed in the second semiconductor layer 3. Additionally, the ranges wherein the diffused resistance interconnections 6 are formed may be controlled so that the ranges wherein the external conducting portions 8 are formed will be within ranges that correspond to the ranges wherein the diffused resistance interconnections 6 are formed in the second semiconductor layer 3. Additionally, both the ranges wherein the external conducting portions 8 are formed in the ranges wherein the diffused resistance interconnections 6 are formed may be controlled so that the ranges wherein the external conducting portions 8 are formed will be within ranges that correspond to the ranges wherein the diffused resistance interconnections 6 are formed in the second semiconductor layer 3.

The present invention can be applied also to pressure sensors having strain gauges having piezoresistance effects for static pressure as well.

1. A pressure sensor including a semiconductor substrate comprising:
an internal resistance portion,
an insulating layer formed on a top of the semiconductor substrate,
an external conducting portion that is formed on top of the insulating layer; and
a contact connecting electrically between the external conducting portion and the internal resistance portion formed in the insulating layer;
wherein the external conducting portion is formed in a range corresponding to the range wherein is formed the internal resistance portion on the semiconductor substrate.

2. A pressure sensor including a semiconductor substrate comprising:
a plurality of internal resistance portions;
an insulating layer formed on a top of the semiconductor substrate;
a plurality of external conducting portions formed on a top of the insulating layer; and
a plurality of contacts connecting electrically between the external conducting portion and the internal resistance portion formed in the insulating layer;
wherein all of the plurality of external conducting portions are formed in ranges corresponding to the ranges wherein is formed the plurality of internal resistance portions on the semiconductor substrate.

3. A pressure sensor as set forth in claim 1, wherein:
the semiconductor substrate is an n-type semiconductor substrate;
an internal resistance portion is made from a p-type semiconductor; and
a voltage is applied so that those parts of the semiconductor substrate outside the internal resistance portion all at least one of the same electropotential or higher than that of the external conducting portion, and so that the potential difference formed between the internal resistance portion of the semiconductor substrate and those parts of the semiconductor substrate outside the internal resistance portion have less than a breakdown voltage.

4. A pressure sensor as set forth in claim 1, wherein:
the semiconductor substrate is a p-type semiconductor substrate;
the internal resistance portion is made from an n-type semiconductor; and
a voltage is applied so that those parts of the semiconductor substrate that are outside the internal resistance portion all at least one of the same electropotential or lower than that of the external conducting portion, and so that the potential difference formed between the internal resistance portion of the semiconductor substrate and those parts of the semiconductor substrate outside the internal resistance portion have less than a breakdown voltage.

5. A pressure sensor as set forth in claim 1, wherein: the number of contacts that are provided in the insulating layer is preferably equal to the number of external conducting portions or less than the number of external conducting portions.

6. A pressure sensor manufacturing method, comprising the steps of:
forming an internal resistance portion in a semiconductor substrate;
forming an insulating layer on top of a semiconductor substrate;
forming an external conducting portion on top of an insulating layer; and
forming a contact for connecting electrically between the external conducting portion and the internal resistance portion in the insulating layer;
wherein:
in the external conducting portion forming process, an external conducting portion is formed in a range corresponding to a range wherein is formed an internal resistance portion on the semiconductor substrate.

7. A pressure sensor manufacturing method as set forth in claim 6, wherein: in the contact forming process, the number of contacts that are formed in the insulating layer is preferably equal to the number of external conducting portions or less than the number of external conducting portions.
